(19) United States
(12) Patent Application Publication
(10) Pub. No.: US 2023/0106479 A1
(43) Pub. Date: Apr. 6, 2023

(54) LUMIPHORIC MATERIAL ARRANGEMENTS FOR MULTIPLE-JUNCTION LIGHT-EMITTING DIODES

(71) Applicant: CreeLED, Inc., Durham, NC (US)

(72) Inventors: Morgan Meadows Davis, Raleigh, NC (US); Colin Blakely, Raleigh, NC (US); Kyle Damborsky, Apex, NC (US); Michael Check, Holly Springs, NC (US)

(21) Appl. No.: 17/494,264

(22) Filed: Oct. 5, 2021

(51) Int. Cl. H01L 33/24; H01L 33/60; H01L 27/15; H01L 33/50

(52) U.S. Cl. CPC H01L 33/24; H01L 33/60; H01L 27/156; H01L 33/504

(57) ABSTRACT

Multiple-junction light-emitting diodes (LEDs), and more particularly lumiphoric material arrangements for multiple-junction LEDs are disclosed. LEDs may refer to multiple-junction LED chips and/or LED packages that include multiple-junction LED chips. Individual lumiphoric material regions may be arranged in positions that are registered with individual junctions of a multiple-junction LED chip. The lumiphoric material regions may be formed at the LED chip level and/or at the LED package level. Different ones of the lumiphoric material regions may be configured to provide different wavelengths in response to recipient light emitted by junctions of the LED chip. In this manner, a single multiple-junction LED chip according to the present disclosure may be capable of providing a plurality of different emission colors and/or wavelengths.

### FIELD OF THE DISCLOSURE

The present disclosure relates to multiple-junction light-emitting diodes (LEDs), and more particularly to lumiphoric material arrangements for multiple-junction LEDs.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

Lumiphoric materials, such as phosphors, may be arranged in light emission paths of LED emitters to convert portions of light to different wavelengths. LED packages have been developed that can provide mechanical support, electrical connections, and encapsulation for LED emitters. Light emissions that exit surfaces of LED emitters typically interact with various elements or surfaces of the LED package and lumiphoric materials before exiting, thereby increasing opportunities for light loss and potential non-uniformity of light emissions. As such, there can be challenges in producing high quality light with desired emission characteristics while also providing high light emission efficiency in LED packages.

The art continues to seek improved LEDs and solid-state lighting devices having desirable illumination characteristics capable of overcoming challenges associated with conventional lighting devices.

### SUMMARY

Aspects disclosed herein relate to multiple-junction light-emitting diodes (LEDs), and more particularly to lumiphoric material arrangements for multiple-junction LEDs. LEDs as disclosed herein may refer to multiple-junction LED chips and/or LED packages that include multiple-junction LED chips. Individual lumiphoric material regions may be arranged in positions that are registered with individual junctions of a multiple-junction LED chip. The lumiphoric material regions may be formed at the LED chip level and/or at the LED package level. Different ones of the lumiphoric material regions may be configured to provide different wavelengths in response to recipient light emitted by junctions of the LED chip. In this manner, a single multiple-junction LED chip according to the present disclosure may be capable of providing a plurality of different emission colors and/or wavelengths.

In one aspect, an LED chip comprises: a substrate comprising a first face and a second face that opposes the first face; an epitaxial layer structure on the first face of the substrate, wherein a plurality of light-emitting junctions is defined in the epitaxial layer structure; and a plurality of lumiphoric material regions on the second face of the substrate, wherein each individual lumiphoric material region of the plurality of lumiphoric material regions is registered with an individual light-emitting junction of the plurality of light-emitting junctions. In certain embodiments, the plurality of lumiphoric material regions comprises a first lumiphoric material region and a second lumiphoric material region that is different than the first lumiphoric material region. In certain embodiments for the LED chip, the plurality of lumiphoric material regions is formed directly on the first face of the substrate. In certain embodiments, a plurality of first streets defines individual light-emitting junctions of the plurality of light-emitting junctions on the first face of the substrate; a plurality of second streets defines individual lumiphoric material regions of the plurality of lumiphoric material regions on the second face of the substrate; and the plurality of first streets is registered with the plurality of second streets. The LED chip may further comprise a light-altering material on portions of the second face of the substrate that are adjacent the plurality of lumiphoric material regions. In certain embodiments, the light-altering material is arranged within the plurality of second streets on the second face of the substrate. In certain embodiments, the light-altering material comprises one or more of a light-reflective material, a light-refractive material, and a light-absorbing material. In certain embodiments, sidewalls of the light-altering material and sidewalls of the substrate are coplanar with one another. In certain embodiments, each light-emitting junction of the plurality of light-emitting junctions is individually controllable. In certain embodiments, a longest lateral dimension of each light-emitting junction of the plurality of light-emitting junctions is in a range from 0.5 millimeters (mm) to 2 mm.

In another aspect, an LED package comprises: a submount; and an LED chip on the submount, the LED chip comprising: a substrate comprising a first face and a second face that opposes the first face; an epitaxial layer structure on the first face of the substrate, wherein a plurality of light-emitting junctions is defined in the epitaxial layer structure; and a plurality of lumiphoric material regions on the second face of the substrate, wherein each individual lumiphoric material region of the plurality of lumiphoric material regions is registered with an individual light-emitting junction of the plurality of light-emitting junctions. The LED package may further comprise a light-altering material on portions of the submount that are adjacent the LED chip. In certain embodiments, a height of the light-altering material from the submount is equal to or less than a height of the plurality of lumiphoric material regions from the submount. In certain embodiments, the height of the light-altering material is greater than a height of the substrate. The LED package may further comprise: a first light-altering material on portions of the substrate that are adjacent the plurality of lumiphoric material regions; and a second light-altering material on portions of the submount that are adjacent the LED chip. In certain embodiments, the plurality of lumiphoric material regions is provided as part of a single wavelength conversion element that is arranged on the substrate. In certain embodiments, each individual lumiphoric material region of the plurality of lumiphoric material regions is provided in an individual wavelength conversion element that is arranged on the substrate.

In another aspect, an LED chip comprises: a substrate comprising a first face and a second face that opposes the first face; an epitaxial layer structure on the first face of the substrate, wherein a plurality of light-emitting junctions is defined in the epitaxial layer structure; and a wavelength conversion element on the second face of the substrate, the wavelength conversion element comprising a plurality of lumiphoric material regions, wherein each individual lumiphoric material region of the plurality of lumiphoric material regions is registered with an individual light-emitting junction of the plurality of light-emitting junctions. In certain embodiments, the wavelength conversion element comprises a binder, and the plurality of lumiphoric material regions is provided within the binder. In certain embodiments, the binder comprises at least one of a ceramic material, a polymer material, and glass. In certain embodiments for the LED chip, a plurality of first streets defines individual light-emitting junctions of the plurality of light-emitting junctions on the first face of the substrate; a plurality of second streets defines individual lumiphoric material regions of the plurality of lumiphoric material regions within the binder; and the plurality of first streets is registered with the plurality of second streets. The LED chip may further comprise an adhesive layer arranged between the wavelength conversion element and the substrate. In certain embodiments, the wavelength conversion element comprises a support element, and the plurality of lumiphoric material regions is provided on a surface of the support element. In certain embodiments, the plurality of lumiphoric material regions is arranged between the support element and the substrate. In certain embodiments for the LED chip, a plurality of first streets defines individual light-emitting junctions of the plurality of light-emitting junctions on the first face of the substrate; a plurality of second streets defines individual lumiphoric material regions of the plurality of lumiphoric material regions on the support element; and the plurality of first streets is registered with the plurality of second streets. The LED chip may further comprise a light-altering material that is arranged within the plurality of second streets.

In another aspect, an LED chip comprises: a substrate comprising a first face and a second face that opposes the first face; an epitaxial layer structure on the first face of the substrate, wherein a plurality of light-emitting junctions is defined in the epitaxial layer structure; and a plurality of wavelength conversion elements on the second face of the substrate, wherein each individual wavelength conversion element of the plurality of wavelength conversion elements is registered with an individual light-emitting junction of the plurality of light-emitting junctions. In certain embodiments, the plurality of wavelength conversion elements comprises at least a first wavelength conversion element with a first lumiphoric material and a second wavelength conversion element with a second lumiphoric material that is different than the first lumiphoric material. In certain embodiments, the plurality of wavelength conversion elements comprises one or more ceramic phosphor plates, phosphor-in-glass structures, phosphor-in-ceramic structures, and single crystal phosphors. The LED chip may further comprise a light-altering material on portions of the second face of the substrate that are adjacent the plurality of wavelength conversion elements. In certain embodiments, a top surface of the light-altering material is coplanar with top surfaces of the plurality of wavelength conversion elements. In certain embodiments, one or more sidewalls of the light-altering material are coplanar with one or more sidewalls of the substrate.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a bottom view of an exemplary light-emitting diode (LED) chip that includes multiple junctions according to embodiments of the present disclosure.

FIG. 1B is a cross-sectional view of the LED chip of FIG. 1A taken along the sectional line 1B-1B of FIG. 1A.

FIG. 1C is a top view of the LED chip of FIG. 1A.

FIG. 2A is a top view of the LED chip of FIG. 1C after a patterned mask is formed on the LED chip in a fabrication step for providing the LED chip with multiple emission color capabilities.

FIG. 2B is a top view of the LED chip of FIG. 2A after blanket application of a first lumiphoric material.

FIG. 2C is a top view of the LED chip of FIG. 2B after removal of the patterned mask and portions of the first lumiphoric material that were formed on the patterned mask.

FIG. 2D is a top view of the LED chip of FIG. 2C after the fabrication steps illustrated in FIGS. 2A-2C are repeated a number of times to form other discrete lumiphoric material regions on the substrate.

FIG. 2E is a top view of a portion of an LED package that includes the LED chip of FIG. 2D on a submount of the LED package.

FIG. 2F is a cross-sectional view of the LED package of FIG. 2E taken along the sectional line 2F-2F of FIG. 2E.

FIG. 2G is a top view of a portion of the LED package of FIG. 2E after a light-altering material has been formed that covers portions of an LED chip's substrate that are adjacent to the lumiphoric material regions and portions of the submount.

FIG. 2H is a cross-sectional view of the LED package of FIG. 2G taken along the sectional line 2H-2H of FIG. 2G.

FIG. 3A is a top view of a portion of an LED chip that is similar to the LED chip of FIG. 2D, but where the light-altering material is formed at the chip level.

FIG. 3B is a cross-sectional view of the LED chip of FIG. 3A taken along the sectional line 3B-3B of FIG. 3A.

FIG. 3C is a cross-sectional view of an LED package that includes the LED chip of FIG. 3B.

FIG. 4A is a top view of an LED package after the LED chip of FIG. 1C is mounted on a submount of the LED package as part of a fabrication sequence where lumiphoric material regions are formed at the LED package level.

FIG. 4B is a top view of the LED package of FIG. 4A after a patterned stencil is formed over a substrate of the LED chip within the package.

FIG. 4C is a top view of the LED package of FIG. 4B after blanket application of a first lumiphoric material.

FIG. 4D is a top view of the LED package of FIG. 4C after removal of the stencil and portions of the first lumiphoric material that were formed on the stencil.

FIG. 4E is a top view of the LED package of FIG. 4D after the fabrication steps illustrated in FIGS. 4B-4C are repeated a number of times to form other discrete lumiphoric material regions on the substrate.

FIG. 4F is a top view of the LED package of FIG. 4E after a light-altering material has been formed that covers portions of the substrate that are adjacent to the lumiphoric material regions and portions of a submount of the LED package.

FIG. 5A is a top view of a wavelength conversion element that includes discrete lumiphoric material regions according to principles of the present disclosure.

FIG. 5B is a cross-sectional view of the wavelength conversion element of FIG. 5A taken along the sectional line 5B-5B of FIG. 5A.

FIG. 5C is a cross-sectional view of a portion of an LED package after the wavelength conversion element of FIGS. 5A and 5B is mounted to the LED chip of FIGS. 1A-1C.

FIG. 6A is a top view of a wavelength conversion element where lumiphoric material regions are provided on a surface of the support element of the wavelength conversion element according to principles of the present disclosure.

FIG. 6B is a cross-sectional view of the wavelength conversion element of FIG. 6A taken along the sectional line 6B-6B of FIG. 6A.

FIG. 6C is a cross-sectional view of the wavelength conversion element of FIG. 6B after a light-altering material is formed on portions of the support element that are adjacent the lumiphoric material regions.

FIG. 6D is a cross-sectional view of a portion of an LED package after the wavelength conversion element of FIG. 6C is mounted to the LED chip of FIGS. 1A-1C.

FIG. 7A is a cross-sectional view of an LED chip before multiple wavelength conversion elements are attached according to principles of the present disclosure.

FIG. 7B is a cross-sectional view of the LED chip of FIG. 7A after attachment of the wavelength conversion elements.

FIG. 7C is a cross-sectional view of the LED chip of FIG. 7B after a light-altering material is provided on portions of the LED chip's substrate that are adjacent the wavelength conversion elements.

FIG. 8 is a cross-sectional view of an exemplary LED package that includes the LED chip of FIG. 2D.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Aspects disclosed herein relate to multiple-junction light-emitting diodes (LEDs), and more particularly to lumiphoric material arrangements for multiple-junction LEDs. LEDs as disclosed herein may refer to multiple-junction LED chips and/or LED packages that include multiple-junction LED chips. Individual lumiphoric material regions may be arranged in positions that are registered with individual junctions of a multiple-junction LED chip. The lumiphoric material regions may be formed at the LED chip level and/or at the LED package level. Different ones of the lumiphoric material regions may be configured to provide different wavelengths in response to recipient light emitted by junctions of the LED chip. In this manner, a single multiple-junction LED chip according to the present disclosure may be capable of providing a plurality of different emission colors and/or wavelengths.

Before delving into specific details of various aspects of the present disclosure, an overview of various elements that may be included in exemplary LEDs of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the ultraviolet (UV) spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. In certain embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof. In other embodiments, the LED chip and corresponding lumiphoric material may be configured to primarily emit converted light from the lumiphoric material so that aggregate emissions include little to no perceivable emissions that correspond to the LED chip itself.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) may be coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

In certain embodiments, one or more lumiphoric materials may be provided as at least a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In some embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may be thinned before or after the patterning process is performed. In certain embodiments, wavelength conversion elements and cover structures may comprise a generally planar upper surface that corresponds to a light emission area of the LED package.

Wavelength conversion elements and cover structures may be attached to one or more LED chips using, for example, a layer of transparent adhesive. In certain embodiments, the layer of the transparent adhesive may include silicone with a refractive index in a range of about 1.3 to about 1.6 that is less than a refractive index of the LED chip on which the wavelength conversion element is placed. In various embodiments, wavelength conversion elements may comprise configurations such as phosphor-in-glass or ceramic phosphor plate arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wirebonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support member, such as a submount or a leadframe. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. In certain aspects, the particles may have an index or refraction that is configured to refract light emissions in a desired direction. In certain aspects, light-reflective particles may also be referred to as light-scattering particles. A weight ratio of the light-reflective particles or scattering particles to a binder may comprise a range of about 1:1 to about 2:1. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast. In certain embodiments, the light-altering material includes both light-reflective material and light-absorbing material suspended in a binder.

Aspects of the present disclosure relate to monolithic LED chips where multiple light-emitting junctions are formed on and supported by a common layer or a substrate. In this manner, a single LED chip may be referred to as a multiple-junction LED chip when multiple light-emitting junctions are arranged on a common layer or substrate of the single LED chip. The multiple light-emitting junctions may be electrically isolated from one another while also being formed from a common LED epitaxial structure. In certain aspects, a common layer, when present, may be provided by a common epitaxial layer that is continuous across the multiple light-emitting junctions. In certain aspects, a common substrate may be provided by a common growth substrate on which the epitaxial structure is initially formed, where the common growth substrate is continuous across the multiple light-emitting junctions. Exemplary methods for forming a multiple-junction LED chip may include blanket epitaxial deposition of a continuous LED epitaxial structure at a wafer level, followed by electrically isolating individual junctions within the LED epitaxial structure. Individual multiple-junction LED chips may then be singulated from the wafer. In this manner, at least one of the common layer and the common substrate may remain in an individual multiple-junction LED chip to provide mechanical support for each of the corresponding junctions.

LED packages have been developed that include multiple LED chips that are clustered together to provide increased light output and/or the capability for a single LED package to emit multiple colors and/or peak wavelengths of light. However, separately formed LED chips may have sizes, shapes, emission profiles, and/or voltage requirements that vary, particular for LED chips that emit different peak wavelengths. Such variations can lead to nonuniform light emissions and/or different voltage requirements for LED chips within a single package. In contrast, multiple-junction LED chips are formed from adjacent portions of a same epitaxial structure, thereby providing more uniform emission wavelengths and/or voltage requirements. Additionally, different junctions within a multiple-junction LED chip are fabricated concurrently, thereby reducing variation in junction sizes, shapes, and emission profiles. Sizes or areas of individual junctions of a multiple-junction LED chip may be scaled according to a desired emission intensity and profile. In certain embodiments, each junction may include a size in a range from smaller sizes such as 0.5 millimeters (mm) by 0.5 mm to larger sizes such as 2 mm by 2 mm, or other ranges from 0.5 mm by 0.5 mm to 1 mm by 1 mm. In certain embodiments, a longest lateral dimension of each junction may be in a range from 0.5 mm to 2 mm, or in a range from 1 mm to 2 mm, or in a range from 0.5 mm to 1 mm. In such ranges where at least one dimension is 0.5 mm and greater, the different junctions of a multiple-junction LED chip may be well suited for providing high output powers in a compact footprint.

In certain aspects, spacing between different junctions may be smaller than what is possible for individual LED chips. In certain embodiments, a width of a street formed between individual junctions may be provided in a range from 20 microns (μm) to 200 μm, or in a range from 20 μm to 100 μm. Such smaller street widths may provide sharper contrast between neighboring junctions, particularly when light-altering materials are present, while also reducing any dark emission spots formed with larger conventional spacings. Larger street widths are also possible depending on the desired application.

Since active epitaxial LED structures are common within multiple-junction LED chips, each of the multiple junctions emits a same emission color or wavelength of light. In order to provide different colored emissions, various lumiphoric material arrangements are disclosed that provide more variable and customizable color options between individual junctions of a multiple-junction LED chip. As such, a single multiple-junction LED chip according to the present disclosure may be capable of providing a plurality of different emission colors and/or wavelengths, including various color combinations of blue, red, green, cyan, amber, etc., as well as various white emissions, such as one or more combinations of warm white, cool white, and neutral white.

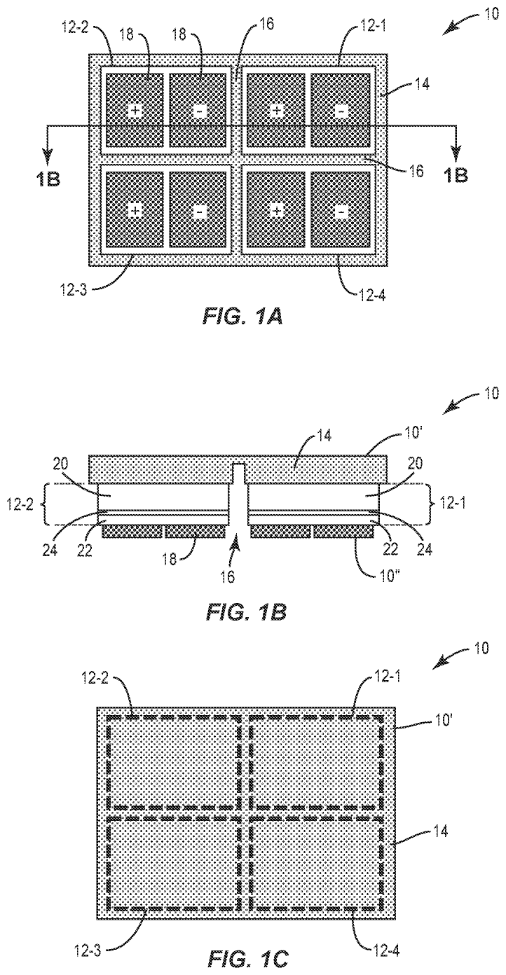

FIG. 1A is a bottom view of an exemplary LED chip 10 that includes multiple junctions 12-1 to 12-4 according to embodiments of the present disclosure. FIG. 1B is a cross-sectional view of the LED chip 10 taken along the sectional line 1B-1B of FIG. 1A. FIG. 1C is a top view of the LED chip 10 of FIG. 1A. As illustrated, the multiple junctions 12-1 to 12-4 are formed on a substrate 14 that is common or continuous across the multiple junctions 12-1 to 12-4. The substrate 14 may include sapphire, SiC, AlN, or GaN. In particular embodiments, the substrate 14 comprises a light-transmissive substrate formed of sapphire or SiC such that the substrate is light transmissive and/or light transparent for wavelengths of light emitted by the multiple junctions 12-1 to 12-4. The multiple junctions 12-1 to 12-4 may be initially formed in a continuous manner on the substrate 14, followed by electrical and/or physical isolation of individual junctions 12-1 to 12-4 by way of streets 16 that are subsequently formed. The streets 16 may be formed by etching or another selective removal process to define the multiple junctions 12-1 to 12-4. The streets 16 may comprise trenches that extend between individual ones of the junctions 12-1 to 12-4. In certain embodiments, the streets 16 may further extend partially into the substrate 14 as best illustrated in FIG. 1B. Dimensions and areas of each of the multiple junctions 12-1 to 12-4 and widths of the streets 16 may be provided in any of the ranges described above. While four of the multiple junctions 12-1 to 12-4 are illustrated, the LED chip 10 may include any number of the junctions 12-1 to 12-4, for example as few as 2 junctions to 30 or more junctions depending on the application. Each of the multiple junctions 12-1 to 12-4 may further include a pair of electrical contacts 18, such as an anode contact and a cathode contact. In this manner, each of the multiple junctions 12-1 to 12-4 may be configured to be individually addressable and/or controllable.

As best illustrated in FIG. 1B, a common epitaxial layer structure is provided that along with the streets 16 defines each of the multiple junctions 12-1 to 12-4. The common epitaxial structure includes at least an n-type layer 20, a p-type layer 22, and an active layer 24 that is arranged between the n-type layer 20 and the p-type layer 22. Since the streets 16 are formed through the common epitaxial layer structure, different discrete portions of the same n-type layer 20, p-type layer 22, and active layer 24 form each of the multiple junctions 12-1 to 12-4. In certain embodiments, the LED chip 10 may be arranged for flip-chip mounting where a primary emission face 10′ of the LED chip 10 is formed opposite a primary mounting face 10″ for the LED chip 10. In this manner, the electrical contacts 18 are arranged at the mounting face 10″ to connect with external electrical connections, such as electrically conductive traces of a submount or circuit board, or a leadframe structure. The substrate 14 may accordingly be provided at the primary emission face 10′ such that emissions generated in each of the multiple junctions 12-1 to 12-4 may propagate through the substrate 14 before escaping the LED chip 10. In this manner, a first face of the substrate 14 may correspond with the primary emission face 10′ and the junctions 12-1 to 12-4 are provided on an opposing second face of the substrate 14. As illustrated in FIG. 1C, locations of each of the multiple junctions 12-1 to 12-4 are provided with superimposed dashed-lines.

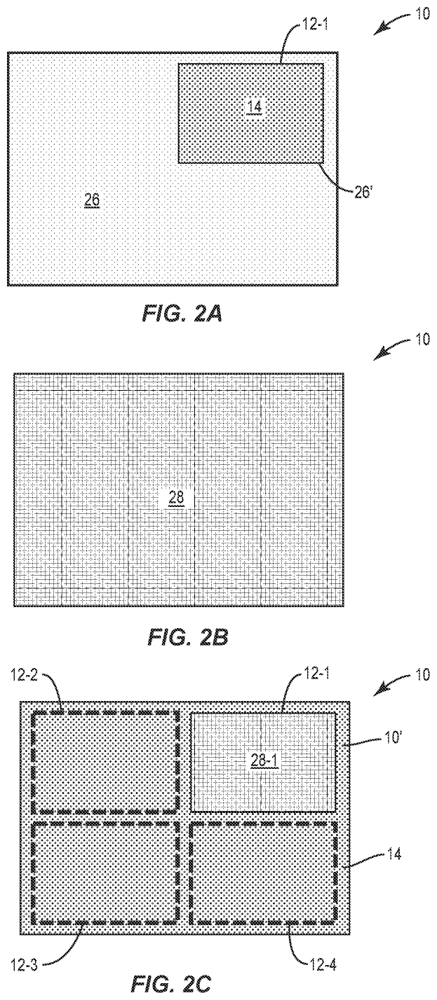

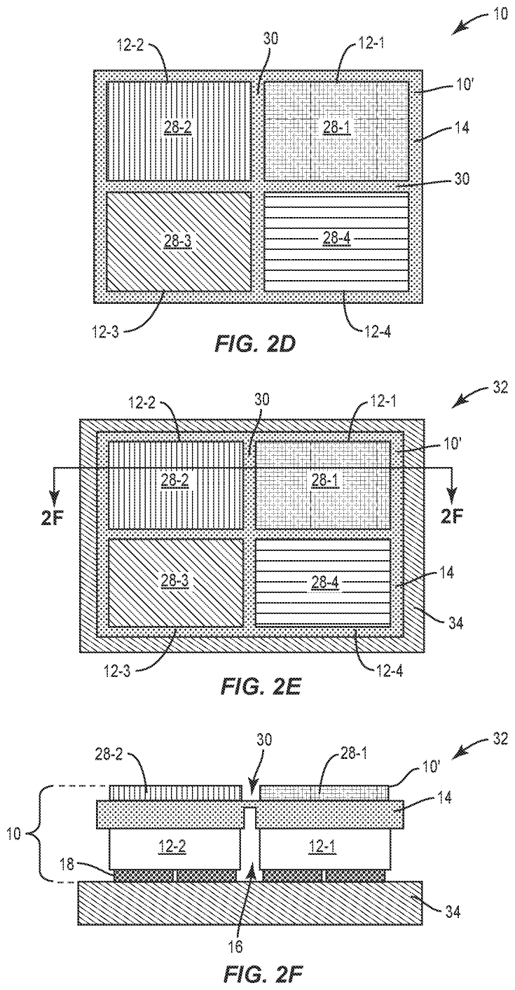

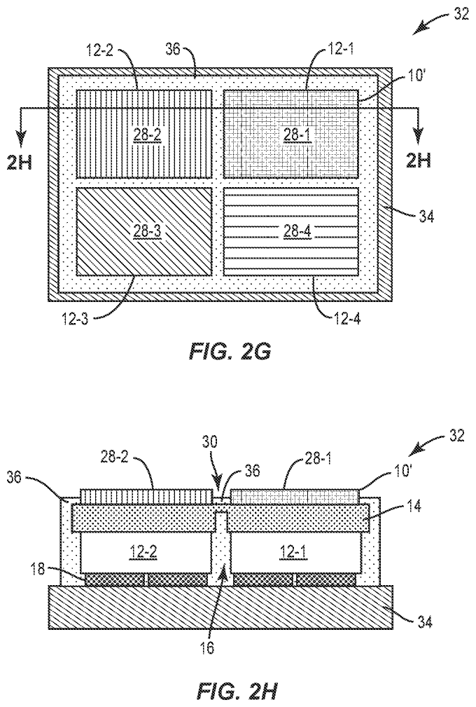

FIGS. 2A-2H illustrate various sequential fabrication steps for providing the LED chip 10 of FIGS. 1A-1C with multiple emission color capabilities where different discrete lumiphoric materials and/or regions 28-1 to 28-4 are formed on the substrate 14.

FIG. 2A is a top view of the LED chip 10 of FIG. 1C after a patterned mask 26 is formed on the LED chip 10. The patterned mask 26 includes an opening 26′ that exposes a portion of the substrate 14 that is registered with the junction 12-1. In certain embodiments, the patterned mask 26 may embody a resist material formed by photolithography. The patterned mask 26 may embody other structures, such as a stencil structure, among other techniques that selectively cover and selectively expose different portions of the substrate 14.

FIG. 2B is a top view of the LED chip 10 of FIG. 2A after blanket application of a lumiphoric material 28. The lumiphoric material 28 may cover the patterned mask 26 and portions of the substrate 14 that are exposed through the opening 26′ from FIG. 2A. Many different application techniques may be employed to form the lumiphoric material 28, including spray coating, dispensing, and printing, among other direct application techniques for forming the lumiphoric material 28 on portions of the substrate 14.

FIG. 2C is a top view of the LED chip 10 of FIG. 2B after removal of the patterned mask 26 and portions of the lumiphoric material 28 that were formed on the patterned mask 26. For photolithography embodiments, the patterned mask 26 may be removed by a resist stripping process. Portions of the lumiphoric material 28 that were formed on the substrate 14 and through the opening 26′ may remain on the substrate 14 to form a discrete lumiphoric material region 28-1 that is registered with the underlying junction 12-1. In certain embodiments, the lumiphoric material region 28-1 is provided directly on a surface of the substrate 14 that corresponds with the primary emission face 10′ for the LED chip 10.

FIG. 2D is a top view of the LED chip 10 of FIG. 2C after the fabrication steps illustrated in FIGS. 2A-2C are repeated a number of times to form other discrete lumiphoric material regions 28-2 to 28-4 on the substrate 14. In this manner, the primary emission face 10′ of the LED chip is arranged to include the lumiphoric material regions 28-2 to 28-4. For the exemplary LED chip 10 illustrated in FIG. 2D, the patterned masking and selective deposition of lumiphoric materials is repeated a total of four times to form each of the discrete lumiphoric material regions 28-1 to 28-4. In other embodiments, the process may be repeated any number of times based on the application. In certain embodiments, another street 30 is formed between adjacent ones of the lumiphoric material regions 28-1 to 28-4 on the substrate 14 such that there is no overlap between different lumiphoric material regions 28-1 to 28-4. The streets 30 may extend on the substrate 14 in a position that is registered with the underlying streets 16 between the junctions 12-1 to 12-4. In this manner, a different one of the lumiphoric material regions 28-1 to 28-4 on one side of the substrate 14 is registered with a corresponding individual junction 12-1 to 12-4 on an opposing side of the substrate 14. In certain embodiments, different ones of the lumiphoric material regions 28-1 to 28-4 may comprise different lumiphoric materials that are configured to provide different emission wavelengths in response to receiving light from the corresponding junction 12-1 to 12-4. In this manner, each of the junctions 12-1 to 12-4 may generate a same peak wavelength that is then subject to different wavelength conversions based on which particular lumiphoric material region 28-1 to 28-4 the light interacts with. Accordingly, the LED chip 10 may emit a plurality of different individual peak wavelengths and/or emission spectrums, alone or in various combinations with one another. In certain embodiments, each of the fabrication steps illustrated in FIGS. 2A to 2C may be performed at a wafer level, followed by a singulation step that provides an individual one of the LED chip 10 as illustrated in FIG. 2D.

FIG. 2E is a top view of a portion of an LED package 32 that includes the LED chip 10 of FIG. 2D. FIG. 2F is a cross-sectional view of the LED package 32 taken along the sectional line 2F-2F of FIG. 2E. The LED chip 10 with discrete lumiphoric material regions 28-1 to 28-4 may be mounted or otherwise attached on a submount 34 of the LED package 32. As previously described, the submount 34 may comprise one or more of a ceramic material, an organic insulator, a PCB, sapphire, Si, a lead frame structure or any other suitable material. As illustrated in FIG. 2F, the discrete lumiphoric material regions 28-1, 28-2 may be registered with their corresponding junctions 12-1, 12-2 that reside on an opposing side of the substrate 14. In certain embodiments, a gap 30 between the lumiphoric material regions 28-1, 28-2 may be registered with the street 16 that is between the corresponding junctions 12-1, 12-2.

FIG. 2G is a top view of a portion of the LED package 32 of FIG. 2E after a light-altering material 36 has been formed that covers portions of the substrate 14 that are adjacent to the lumiphoric material regions 28-1 to 28-4 and portions of the submount 34. FIG. 2H is a cross-sectional view of the LED package 32 taken along the sectional line 2H-2H of FIG. 2G. The light-altering material 36 may be provided to surround lateral edges of each of the lumiphoric material regions 28-1 to 28-4. Additionally, the light-altering material 36 may be provided on portions of the substrate 14 that are in the streets 30. In this manner, the primary emission face 10′ of the underlying LED chip may include only the lumiphoric material regions 28-1 to 28-4 and the light-altering material 36. In certain embodiments, the light-altering material 36 may be provided on portions of the submount 34 that are adjacent the junctions 12-1, 12-2, thereby arranging the light-altering material 36 to surround lateral edges of both the lumiphoric material regions 28-1 to 28-4 and the junctions 12-1 to 12-4. In this manner, the light-altering material 36 may also be arranged in the streets 16 between adjacent junctions 12-1 to 12-4. In certain embodiments, a height of the light-altering material 36 from the submount 34 may be arranged to be equal to or less than a height of the lumiphoric material regions 28-1 to 28-4 in order to reduce amounts of the light-altering material 36 that wicks or otherwise propagates over the lumiphoric material regions 28-1 to 28-4. The height of the light-altering material 36 from the submount 34 may be greater than a corresponding height of the substrate 14 such that light emitted from the junctions 12-1 to 12-4 may primarily be directed through the lumiphoric material regions 28-1 to 28-4.

As previously described, the light-altering material 36 may include one or more combinations of light-reflective materials, light-refractive materials, and light-absorbing materials, depending on the desired emission characteristics for the LED package 32. When the light-altering material 36 primarily includes light-reflective and/or light-refractive materials, laterally propagating light within the lumiphoric material regions 28-1 to 28-4 and/or the junctions 12-1 to 12-4 may be redirected toward and out of one or more portions of the primary emission face 10′. When light-absorbing materials are present in the light-altering material 36, alone or in combination with light-reflective and/or light-refractive materials, the LED package 32 may exhibit increased contrast between the different emission regions defined by the lumiphoric material regions 28-1 to 28-4.

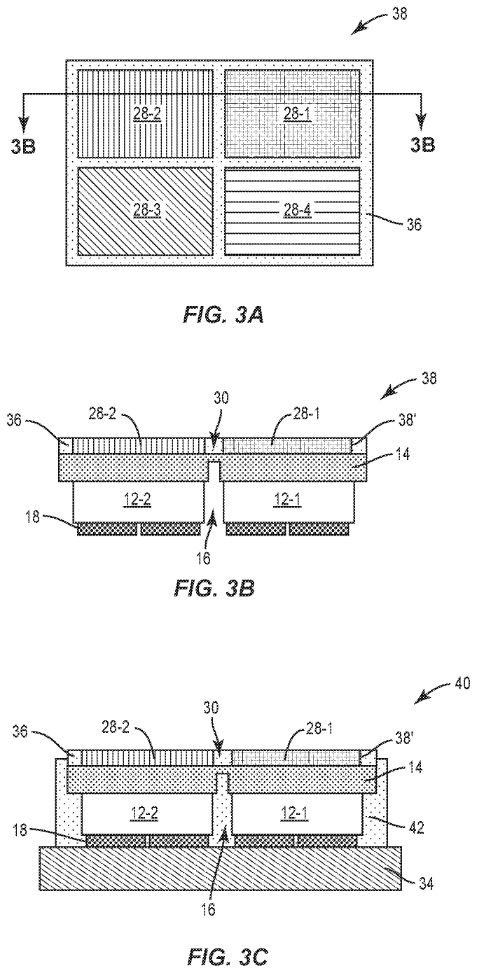

FIGS. 3A-3C illustrate an alternative fabrication sequence for FIGS. 2E-2H where the light-altering material 36 is applied at the LED chip level rather than the LED package level. In this regard, the fabrication steps illustrated in FIGS. 3A-3C may begin after the LED chip 10 of FIG. 2D is formed, either individually or at the wafer level before singulation.

FIG. 3A is a top view of a portion of an LED chip 38 that is similar to the LED chip 10 of FIG. 2D, but where the light-altering material 36 is formed at the chip level. FIG. 3B is a cross-sectional view of the LED chip 38 taken along the sectional line 3B-3B of FIG. 3A. As illustrated, the light-altering material 36 may be arranged to cover portions of the substrate 14 that are adjacent to the lumiphoric material regions 28-1 to 28-4 at a primary emission face 38′ of the LED chip 38. In certain embodiments, the light-altering material 36 may be arranged only on the same face of the substrate 14 on which the lumiphoric material regions 28-1 to 28-4 reside. This may result from fabrication steps where the light-altering material 36 is applied at the wafer level before the individual LED chip 38 is singulated. In certain embodiments, sidewalls of the light-altering material 36 and sidewalls of the substrate 14 may be vertically aligned and/or coplanar with one another along lateral sides of the LED chip 38. In certain embodiments, a top surface of the light-altering material 36 may be coplanar with top surfaces of the lumiphoric material regions 28-1 to 28-4. For such embodiments, a planarization process may be applied at the wafer level that forms the coplanar relationship between the light-altering material 36 and the lumiphoric material regions 28-1 to 28-4.

FIG. 3C is a cross-sectional view of an LED package 40 that includes the LED chip 38 of FIG. 3B. As illustrated, the LED chip 38 may be mounted on the submount 34 of the LED package 40. In certain embodiments, an underfill material 42 may be provided between portions of the submount 34 and one or more of the junctions 12-1 to 12-4 and the substrate 14. The underfill material 42 may further surround lateral edges of the substrate 14 and/or the junctions 12-1 to 12-4. In certain embodiments, the underfill material 42 and the light-altering material 36 may comprise a same material that is one or more of light-reflective, light-refractive, and light-absorbing. In other embodiments, the underfill material 42 and light-altering material 36 may comprise different materials or material combinations that provide different light-altering characteristics. For example, the underfill material 42 and the light-altering material 36 may both include light-reflective and/or light-refractive materials while the light-altering material 36 further includes light-absorbing materials. In this manner, the underfill material 42 may serve to redirect light toward the primary emission face 38′ and the light-altering material 36 may further provided increased contrast between the lumiphoric material regions 28-1 to 28-4 at the primary emission face 38′.

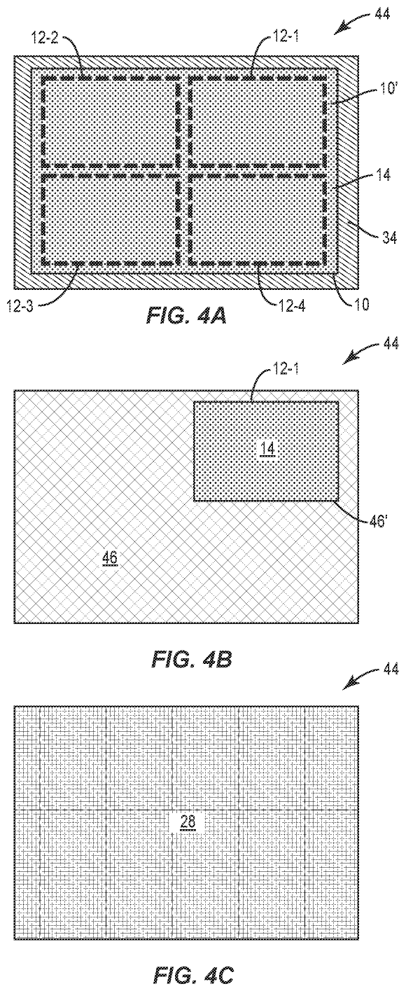

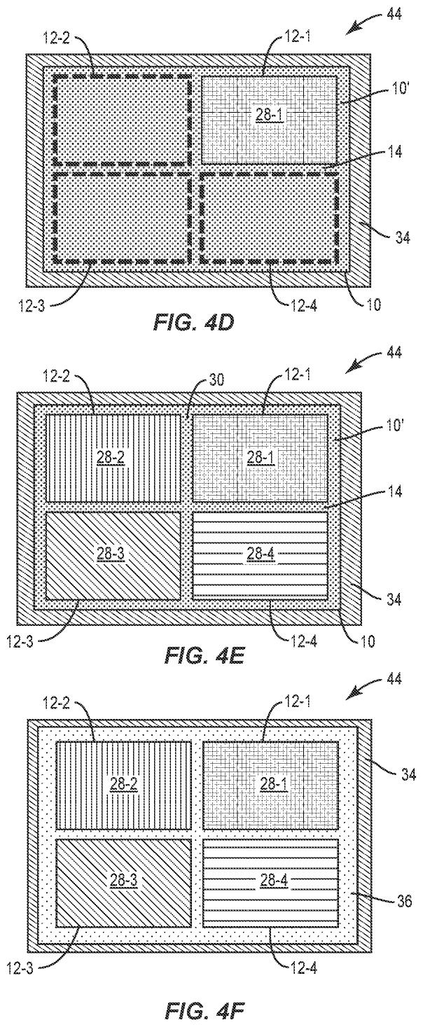

FIGS. 4A-4F illustrate an alternative fabrication sequence for FIGS. 2A-2H where the lumiphoric material regions 28-1 to 28-4 are applied at the LED package level rather than the LED chip level. In this regard, the lumiphoric material regions 28-1 to 28-4 may be configured to a specific application after mounting within the LED package, rather than being pre-configured at the chip level.

FIG. 4A is a top view of an LED package 44 after the LED chip 10 of FIG. 1C is mounted on the submount 34 of the LED package 44. As illustrated, the LED chip 10 is assembled within the LED package 44 before the lumiphoric material regions 28-1 to 28-4 are applied. In this manner, the junctions 12-1 to 12-4 are provided between the substrate 14 and the submount 34, and a face of the substrate 14 that is opposite the junctions 12-1 to 12-4 and the submount 34 forms the primary emission face 10′ for the LED chip 10.

FIG. 4B is a top view of the LED package 44 of FIG. 4A after a patterned stencil 46 is formed over the substrate 14. The patterned stencil 46 includes an opening 46′ that exposes a portion of the substrate 14 that is registered with the junction 12-1. The patterned stencil 46 may embody other structures, such as a resist material as described above for FIG. 2A, among other techniques that selectively cover and selectively expose different portions of the substrate 14.

FIG. 4C is a top view of the LED package 44 of FIG. 4B after blanket application of the lumiphoric material 28. The lumiphoric material 28 may cover the patterned stencil 46 and portions of the substrate 14 that are exposed through the opening 46′ from FIG. 4B. Many different application techniques may be employed to form the lumiphoric material 28, including spray coating, dispensing, and printing, among other direct application techniques for forming the lumiphoric material 28 on portions of the substrate 14.

FIG. 4D is a top view of the LED package 44 of FIG. 4C after removal of the stencil 46 and portions of the lumiphoric material 28 that were formed on the stencil 46. Portions of the lumiphoric material 28 that were formed on the substrate 14 and through the opening 46′ may remain on the substrate 14 to form the discrete lumiphoric material region 28-1 that is registered with the underlying junction 12-1. In certain embodiments, the lumiphoric material region 28-1 is provided directly on a surface of the substrate 14 that corresponds with the primary emission face 10′ for the LED chip 10. As further illustrated in FIG. 4E, the fabrication steps illustrated in FIGS. 4B-4C are repeated a number of times to form other discrete lumiphoric material regions 28-2 to 28-4 on the substrate 14. In this manner, the primary emission face 10′ of the LED chip 10 is arranged to include the lumiphoric material regions 28-2 to 28-4. Accordingly, the LED package 44 of FIG. 4E may be similar to the LED package 32 of FIG. 2E.

FIG. 4F is a top view of the LED package 44 of FIG. 4E after the light-altering material 36 has been formed that covers portions of the substrate 14 that are adjacent to the lumiphoric material regions 28-1 to 28-4 and portions of the submount 34. In this manner, the LED package 44 of FIG. 4F is similar to the LED package 32 of FIG. 2G, with a primary difference being the timing for application of the lumiphoric material regions 28-1 to 28-4 at either the package level (e.g., FIG. 4F) or the chip level (e.g., FIG. 2G).

As described above, discrete lumiphoric material regions may be formed on or directly on one or more surfaces of a multiple-junction LED chip. In this manner, each of the discrete lumiphoric material regions may be registered with a different individually addressable junction of the multiple-junction LED chip. In other embodiments, the principles of the present disclosure are applicable to providing discrete lumiphoric material regions in the form of one or more pre-formed structures that may be attached to the multiple-junction LED chip. In this regard, each of the discrete lumiphoric material regions may also be registered with a different individually addressable junction of the multiple-junction LED chip. The pre-formed structures may include various wavelength conversion elements, such a single wavelength conversion element that includes multiple discrete lumiphoric material regions and/or multiple pre-formed structures that may be separately attached to a single multiple-junction LED chip.

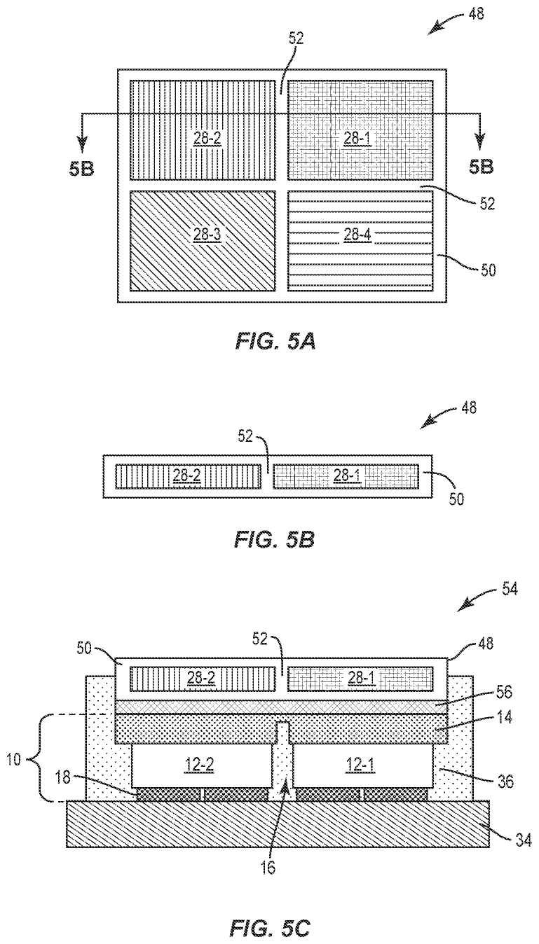

FIGS. 5A-5C illustrate a fabrication sequence where a single wavelength conversion element 48 is provided as a preformed structure that may be subsequently attached to the LED chip 10 of FIGS. 1A-1C. FIG. 5A is a top view of the wavelength conversion element 48 that includes discrete lumiphoric material regions 28-1 to 28-4. FIG. 5B is a cross-sectional view of the wavelength conversion element 48 taken along the sectional line 5B-5B of FIG. 5A. The wavelength conversion element 48 may be formed with individual and discrete lumiphoric material regions 28-1 to 28-4 that are formed within a binder 50. The lumiphoric material regions 28-1 to 28-4 may be laterally separated from one another by one or more streets 52 of the binder 50. The binder 50 may embody may different materials that provide mechanical support for the wavelength conversion element 48 and embedded lumiphoric material regions 28-1 to 28-4. The binder 50 may comprise one or more of a ceramic material, a polymer material, and glass. In the case of a ceramic material, the wavelength conversion element 48 may be arranged with the lumiphoric material regions 28-1 to 28-4 before sintering or firing of the binder 50. In the case of a polymer material, such as silicone, the wavelength conversion element 48 may be arranged with the lumiphoric material regions 28-1 to 28-4 before curing or cross-linking of the binder 50. In certain aspects, the binder 50 may be light-transparent to one or more wavelengths of light from the lumiphoric material regions 28-1 to 28-4 and corresponding LED emissions that are received by the wavelength conversion element 48. In certain embodiments, the binder 50 may further include one or more materials that provide one or more of light-reflective, light-refractive, and light-absorbing particles as previously described. In certain embodiments, the wavelength conversion element 48 may be formed as part of a larger sheet that is singulated before LED chip and/or package mounting.

FIG. 5C is a cross-sectional view of a portion of an LED package 54 after the wavelength conversion element 48 of FIGS. 5A and 5B is mounted to the LED chip 10 of FIGS. 1A-1C. The wavelength conversion element 48 may be attached to the substrate 14 of the LED chip 10 by way of an adhesive layer 56. In certain embodiments, the adhesive layer 56 comprises a material that is light-transparent to wavelengths of light generated by the junctions 12-1 to 12-4 and/or the lumiphoric material regions 28-1 to 28-4. For example, the adhesive layer 56 may comprise silicone, other transparent polymers, and/or transparent epoxy. As illustrated, the streets 52 of the binder 50 may align or otherwise be registered with the streets 16 of the underlying LED chip 10. In certain embodiments, the wavelength conversion element 48 may be attached to the LED chip 10 before the LED chip 10 is provided on the submount 34. In this manner, the combination of the multiple junctions 12-1 to 12-2, the substrate 14, the adhesive layer 56, and the wavelength conversion element 48 may also be referred to as an LED chip. In other embodiments, the LED chip 10 may be mounted on the submount 34 before the wavelength conversion element 48 and adhesive layer 56 are provided. In still further embodiments, the LED package 54 may include the light-altering material 36 as previously described. The light-altering material may be provided with a height above the submount 34 that extends above the LED chip 10 and the adhesive layer 56. The light-altering material 36 may further extend along sidewall portions of the wavelength conversion element 48.

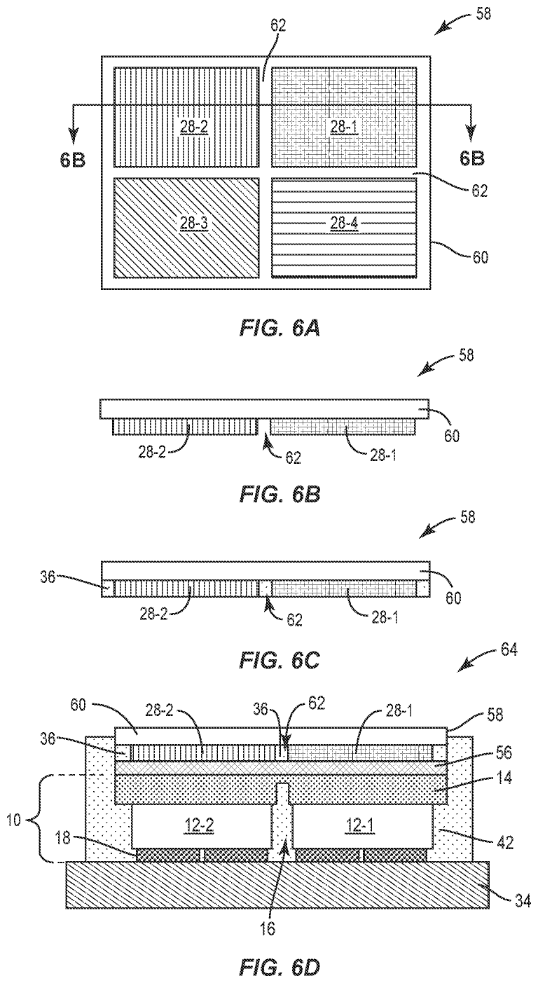

FIGS. 6A-6D illustrate another fabrication sequence where a single wavelength conversion element 58 is provided as a preformed structure that may be subsequently attached to the LED chip 10 of FIGS. 1A-1C. In the fabrication sequence of FIGS. 6A-6D, the wavelength conversion element 58 comprises a support element 60 on which the lumiphoric material regions 28-1 to 28-4 are provided. Relative to wavelengths of light provided by the junctions 12-1 to 12-4 and the lumiphoric material regions 28-1 to 28-4, the support element 60 may comprise a light-transparent material, a semi-transparent material, or a light-transmissive material, such as sapphire, SiC, silicone, and/or glass (e.g., borosilicate and/or fused quartz).

FIG. 6A is a top view of the wavelength conversion element 58 where the lumiphoric material regions 28-1 to 28-4 are provided on a surface of the support element 60 of the wavelength conversion element 58. FIG. 6B is a cross-sectional view of the wavelength conversion element 58 taken along the sectional line 6B-6B of FIG. 6A. The lumiphoric material regions 28-1 to 28-4 may be formed on or directly on a surface of the support element 60. In certain embodiments, individual ones of the lumiphoric material regions 28-1 to 28-4 may be selectively formed on the support element 60 in a sequential manner. Such fabrication steps include forming different ones of the lumiphoric material regions 28-1 to 28-4 through different patterned masks or stencils in a similar manner as described above for FIGS. 2A-2D and/or FIGS. 4B-4E. In certain embodiments, the lumiphoric material regions 28-1 to 28-4 are formed in a discrete manner such that one or more streets 62 of the wavelength conversion element 58 are defined between adjacent pairs of the lumiphoric material regions 28-1 to 28-4.

FIG. 6C is a cross-sectional view of the wavelength conversion element 58 of FIG. 6B after the light-altering material 36 is formed on portions of the support element 60 that are adjacent the lumiphoric material regions 28-1 to 28-4. In this regard, FIG. 6C illustrates an embodiment where the wavelength conversion element 58 is preformed with the light-altering material 36. The light-altering material 36 may be formed on surfaces of the support element 60 that are within the streets 62 and/or along a perimeter of the lumiphoric material regions 28-1 to 28-4. In certain embodiments, the support element 60 may be singulated from a larger sheet after the lumiphoric material regions 28-1 to 28-4 and the light-altering material 36 have been formed on the larger sheet. In this manner, sidewalls of the support element 60 and the light-altering material 36 may be self-aligned in a vertical manner. As further illustrated in FIG. 6C, the light-altering material 36 and the lumiphoric material regions 28-1 to 28-4 may be arranged in a coplanar manner on a surface of the support element 60, thereby providing a smooth surface for later mounting. In other embodiments, the light-altering material 36 may be omitted and the fabrication step illustrated in FIG. 6C may be skipped.

FIG. 6D is a cross-sectional view of a portion of an LED package 64 after the wavelength conversion element 58 of FIG. 6C is mounted to the LED chip 10 of FIGS. 1A-1C. The wavelength conversion element 58 may be attached to the substrate 14 of the LED chip 10 by way of the adhesive layer 56 as previously described for FIG. 5C. In certain embodiments, the wavelength conversion element 58 may be mounted to the LED chip 10 such that the lumiphoric material regions 28-1 to 28-4 are arranged between the support element 60 and the LED chip 10. This arrangement may allow the support element 60 to shield the lumiphoric material regions 28-1 to 28-4 from environmental exposure during operation, thereby reducing degradation due to contamination. Additionally, the light-altering material 36 may be arranged between the adhesive layer 56 and the support element 60. As such, light from the junctions 12-1 to 12-4 may readily pass through the substrate 14 and the adhesive layer 56 before being directed into each of the lumiphoric material regions 28-1 to 28-4. In certain embodiments, the underfill material 42 may be provided between portions of the submount 34 and one or more of the junctions 12-1 to 12-4 and/or the substrate 14 as described above for FIG. 3C. The underfill material 42 may further surround lateral edges of the substrate 14, the junctions 12-1 to 12-4, and portions of the wavelength conversion element 58. In certain embodiments, the underfill material 42 and the light-altering material 36 may comprise a same material that is one or more of light-reflective, light-refractive, and light-absorbing. In other embodiments, the underfill material 42 and light-altering material 36 may comprise different materials or material combinations that provide different light-altering characteristics. For embodiments where the light-altering material 36 is omitted from the wavelength conversion element 58, the underfill material 42 may form a primary light-altering material for the LED package 64.

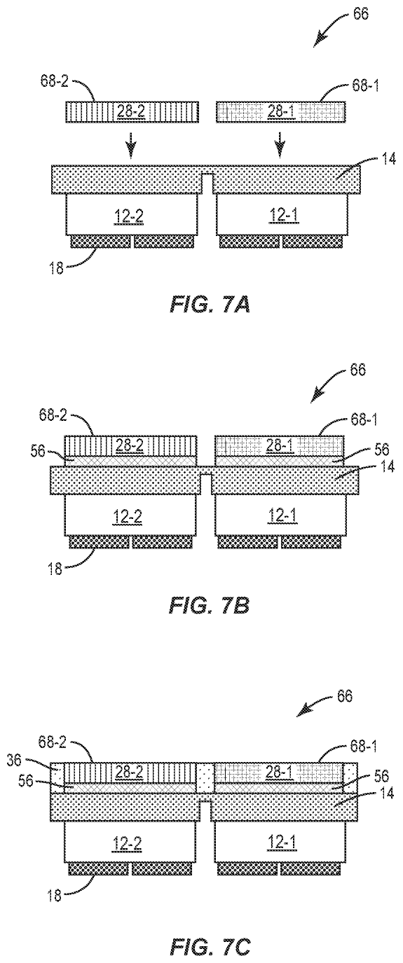

FIGS. 7A-7C illustrate another fabrication sequence for an LED chip 66 where multiple wavelength conversion elements 68-1 to 68-2 are provided as preformed structures that are subsequently attached to the LED chip 66. The LED chip 66 may include the substrate 14, the junctions 12-1 to 12-2, and the electrical contacts 18 in a similar manner as previously described for the LED chip 10 of FIGS. 1A-1C.

FIG. 7A is a cross-sectional view of the LED chip 66 before the wavelength conversion elements 68-1 to 68-2 are attached, and FIG. 7B is a cross-sectional view of the LED chip 66 of FIG. 7A after the wavelength conversion elements 68-1 to 68-2 are attached. In certain embodiments, different ones of the wavelength conversion elements 68-1 to 68-2 may be formed separately from one another, depending on the specific lumiphoric material region 28-1, 28-2 that is present. The wavelength conversion elements 68-1 to 68-2 may embody one or more of the wavelength conversion elements 48 of FIGS. 5A to 5C, the wavelength conversion elements 58 of FIGS. 6A to 6D, ceramic phosphor plates, phosphor-in-glass structures, phosphor-in-ceramic structures, single crystal phosphors, and combinations thereof. While only two wavelength conversion elements 68-1 to 68-2 are illustrated in the cross-sectional views, any number of the wavelength conversion elements 68-1 to 68-2 may be present, depending on the intended quantity of different emissions that are provided by the LED chip 66. Each of the wavelength conversion elements 68-1 to 68-2 may be attached to different portions of the substrate 14 by way of separate adhesive layers 56. In alternative configurations, the adhesive layer 56 may be formed as a single and continuous layer across the wavelength conversion elements 68-1 to 68-2. FIG. 7C is a cross-sectional view of the LED chip 66 of FIG. 7B, after the light-altering material 36 is provided on portions of the substrate 14 that are adjacent the wavelength conversion elements 68-1, 68-2. In certain embodiments, a top surface of the light-altering material 36 may be coplanar with a top surface the wavelength conversion elements 68-1, 68-2. Additionally, sidewalls of the light-altering material 36 may be coplanar with sidewalls of the substrate 14.

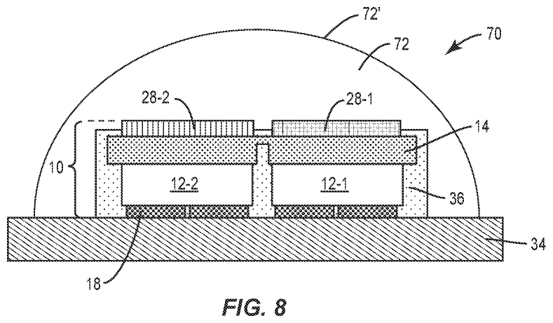

Embodiments of the present disclosure may be well suited for use in any number of packaged LED components. Such packages may include submounts, light-altering materials and/or underfill materials, encapsulants, and lenses, among other component elements. FIG. 8 is a cross-sectional view of an exemplary LED package 70 that includes the LED chip 10 of FIG. 2D. The LED package 70 may include the LED chip 10, the submount 34, and the light-altering material 36 as previously described. While the LED chip 10 of FIG. 2D is illustrated, the LED package 70 may include the LED chip 38 of FIGS. 3A to 3C, the LED chip 10 and lumiphoric material regions 28-1 to 28-4 of FIGS. 4A to 4F, any of the LED chip 10 and wavelength conversion elements 48, 58 of FIGS. 5A to 5C and FIGS. 6A to 6D, or the LED chip 66 of FIGS. 7A to 7C.

In FIG. 8, the LED package 70 includes an encapsulant 72 that may provide both environmental and/or mechanical protection for the LED chip 10. The encapsulant 72 may also be referred to as an encapsulant layer. The encapsulant 72 may be provided to encapsulate exposed portions of the LED chip 10, the lumiphoric material regions 28-1 to 28-2, the light-altering material 36 (when present), and one or more portions of the submount 34 that are adjacent the LED chip 10. The encapsulant 72 may be provided to cover and contact or directly contact such portions of the LED package 70. Many different materials can be used for the encapsulant 72, including silicone, plastic, epoxy or glass, with a suitable material being compatible with various molding processes. In certain embodiments, silicone is suitable for molding and provides suitable optical transmission properties for light provided by the LED chip 10 and/or the lumiphoric material regions 28-1, 28-2. The encapsulant 72 may be molded into the shape of a lens 72′ that serves to shape an overall emission pattern for the LED package 70. Depending on the desired emission pattern, the lens 72′ may form many different shapes, including hemispheric, ellipsoid bullet, flat, hex-shaped and square. In some embodiments, a suitable shape for the lens 72′ includes both curved and planar surfaces. It is understood that the encapsulant 72 may also be textured to improve light extraction or contain materials such as phosphors or scattering particles.

The principles of the present disclosure may provide multiple-junction LED chips and corresponding LED packages that are capable of providing a plurality of different emission colors and/or wavelengths. Such multiple-junction LED chips may be well suited to provide compact footprints in high output power applications where a variety of multiple color emissions are provided, such as entertainment and/or architectural lighting applications, among others.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
a substrate comprising a first face and a second face that opposes the first face;
an epitaxial layer structure on the first face of the substrate, wherein a plurality of light-emitting junctions is defined in the epitaxial layer structure; and
a plurality of lumiphoric material regions on the second face of the substrate, wherein each individual lumiphoric material region of the plurality of lumiphoric material regions is registered with an individual light-emitting junction of the plurality of light-emitting junctions.

2. The LED chip of claim 1, wherein the plurality of lumiphoric material regions comprises a first lumiphoric material region and a second lumiphoric material region that is different than the first lumiphoric material region.

3. The LED chip of claim 1, wherein the plurality of lumiphoric material regions is formed directly on the first face of the substrate.

4. The LED chip of claim 1, wherein:
a plurality of first streets defines individual light-emitting junctions of the plurality of light-emitting junctions on the first face of the substrate;
a plurality of second streets defines individual lumiphoric material regions of the plurality of lumiphoric material regions on the second face of the substrate; and
the plurality of first streets is registered with the plurality of second streets.

5. The LED chip of claim 1, further comprising a light-altering material on portions of the second face of the substrate that are adjacent the plurality of lumiphoric material regions.

6. The LED chip of claim 5, wherein the light-altering material is arranged within the plurality of second streets on the second face of the substrate.

7. The LED chip of claim 5, wherein the light-altering material comprises one or more of a light-reflective material, a light-refractive material, and a light-absorbing material.

8. The LED chip of claim 5, wherein sidewalls of the light-altering material and sidewalls of the substrate are coplanar with one another.

9. The LED chip of claim 1, wherein each light-emitting junction of the plurality of light-emitting junctions is individually controllable.

10. The LED chip of claim 1, wherein a longest lateral dimension of each light-emitting junction of the plurality of light-emitting junctions is in a range from 0.5 millimeters (mm) to 2 mm.

11. A light-emitting diode (LED) package comprising:
a submount; and
an LED chip on the submount, the LED chip comprising:
a substrate comprising a first face and a second face that opposes the first face;
an epitaxial layer structure on the first face of the substrate, wherein a plurality of light-emitting junctions is defined in the epitaxial layer structure; and
a plurality of lumiphoric material regions on the second face of the substrate, wherein each individual lumiphoric material region of the plurality of lumiphoric material regions is registered with an individual light-emitting junction of the plurality of light-emitting junctions.

12. The LED package of claim 11, further comprising a light-altering material on portions of the submount that are adjacent the LED chip.

13. The LED package of claim 11, wherein a height of the light-altering material from the submount is equal to or less than a height of the plurality of lumiphoric material regions from the submount.

14. The LED package of claim 13, wherein the height of the light-altering material is greater than a height of the substrate.

15. The LED package of claim 11, further comprising:
a first light-altering material on portions of the substrate that are adjacent the plurality of lumiphoric material regions; and
a second light-altering material on portions of the submount that are adjacent the LED chip.

16. The LED package of claim 11, wherein the plurality of lumiphoric material regions is provided as part of a single wavelength conversion element that is arranged on the substrate.

17. The LED package of claim 11, wherein each individual lumiphoric material region of the plurality of lumiphoric material regions is provided in an individual wavelength conversion element that is arranged on the substrate.

18. A light-emitting diode (LED) chip comprising:
a substrate comprising a first face and a second face that opposes the first face;
an epitaxial layer structure on the first face of the substrate, wherein a plurality of light-emitting junctions is defined in the epitaxial layer structure; and
a wavelength conversion element on the second face of the substrate, the wavelength conversion element comprising a plurality of lumiphoric material regions, wherein each individual lumiphoric material region of the plurality of lumiphoric material regions is registered with an individual light-emitting junction of the plurality of light-emitting junctions.

19. The LED chip of claim 18, wherein the wavelength conversion element comprises a binder, and the plurality of lumiphoric material regions is provided within the binder.

20. The LED chip of claim 19, wherein the binder comprises at least one of a ceramic material, a polymer material, and glass.

21. The LED chip of claim 19, wherein:
a plurality of first streets defines individual light-emitting junctions of the plurality of light-emitting junctions on the first face of the substrate;
a plurality of second streets defines individual lumiphoric material regions of the plurality of lumiphoric material regions within the binder; and
the plurality of first streets is registered with the plurality of second streets.

22. The LED chip of claim 18, further comprising an adhesive layer arranged between the wavelength conversion element and the substrate.

23. The LED chip of claim 18, wherein the wavelength conversion element comprises a support element, and the plurality of lumiphoric material regions is provided on a surface of the support element.

24. The LED chip of claim 23, wherein the plurality of lumiphoric material regions is arranged between the support element and the substrate.

25. The LED chip of claim 23, wherein:
a plurality of first streets defines individual light-emitting junctions of the plurality of light-emitting junctions on the first face of the substrate;
a plurality of second streets defines individual lumiphoric material regions of the plurality of lumiphoric material regions on the support element; and
the plurality of first streets is registered with the plurality of second streets.

26. The LED chip of claim 25, further comprising a light-altering material that is arranged within the plurality of second streets.

27. A light-emitting diode (LED) chip comprising:
a substrate comprising a first face and a second face that opposes the first face;
an epitaxial layer structure on the first face of the substrate, wherein a plurality of light-emitting junctions is defined in the epitaxial layer structure; and
a plurality of wavelength conversion elements on the second face of the substrate, wherein each individual wavelength conversion element of the plurality of wavelength conversion elements is registered with an individual light-emitting junction of the plurality of light-emitting junctions.

28. The LED chip of claim 27, wherein the plurality of wavelength conversion elements comprises at least a first wavelength conversion element with a first lumiphoric material and a second wavelength conversion element with a second lumiphoric material that is different than the first lumiphoric material.

29. The LED chip of claim 27, wherein the plurality of wavelength conversion elements comprises one or more ceramic phosphor plates, phosphor-in-glass structures, phosphor-in-ceramic structures, and single crystal phosphors.

30. The LED chip of claim 27, further comprising a light-altering material on portions of the second face of the substrate that are adjacent the plurality of wavelength conversion elements.

31. The LED chip of claim 30, wherein a top surface of the light-altering material is coplanar with top surfaces of the plurality of wavelength conversion elements.

32. The LED chip of claim 30, wherein one or more sidewalls of the light-altering material are coplanar with one or more sidewalls of the substrate.
